(19) United States
(12) Patent Application Publication
(10) Pub. No.: US 2013/0248906 A1
(43) Pub. Date: Sep. 26, 2013

(54) LIGHT EMITTING DIODE PACKAGE STRUCTURE AND METHOD FOR FABRICATING THE SAME

(71) Applicant: DELTA ELECTRONICS, INC., Taoyuan Hsien (TW)

(72) Inventor: Horng-Jou WANG, Taoyuan Hsien (TW)

(73) Assignee: DELTA ELECTRONICS, INC., Taoyuan Hsien (TW)

(21) Appl. No.: 13/626,483

(22) Filed: Sep. 25, 2012

(30) Foreign Application Priority Data
Mar. 26, 2012 (TW) 101110295

(51) Int. Cl. H01L 33/50; H01L 33/58

(52) U.S. Cl. 257/98; 438/29; 257/E33.061; 257/E33.067

(57) ABSTRACT

The invention provides a light emitting diode package structure and a method for fabricating the same. The package structure includes: a light emitting diode chip formed on a substrate; a first hydrophobic rib layer formed on the substrate and surrounding the light emitting diode; and a first cover layer formed on the substrate and covering the light emitting diode, wherein the first hydrophobic rib layer is used as a border of the first cover layer and an angle between the facet of the first cover layer and the substrate is about 60-90 degrees.

### CROSS REFERENCE TO RELATED APPLICATIONS

This application claims priority of Taiwan Patent Application No. 101110295, filed on Mar. 26, 2012, the entirety of which is incorporated by reference herein.

### BACKGROUND OF THE INVENTION

1. Field of the Invention

The present invention relates to a light emitting diode package structure, and in particular relates to a light emitting diode package structure having a hydrophobic rib layer.

2. Description of the Related Art

Because light emitting diodes (LED) have several advantages over conventional lamps, such as a small size, a long lifespan, low power consumption, high response speed, etc., considerable research attention has been recently focused on development thereof.

FIG. 1 shows a cross-sectional schematic representation of a light emitting diode package structure 10 in prior art by a molding process. The light emitting diode package structure 10 includes a substrate 12, a light emitting diode chip 14, a conductive wire 16 and an encapsulant 18. The light emitting diode chip 14 is formed on the substrate 12. The light emitting diode chip 14 is electrically connected to a conductive pads (not shown in FIG. 1) on the substrate 12 by the conductive wire 16. The light emitting diode chip 14 is covered by the encapsulant 18.

In a conventional molding process, a release film is formed on a mold for stripping step. However, the material of the release film is unique and the cost of the mold equipment is high. Additionally, a certain thickness is required between the adjacent light emitting diode chips 14, and thus the light emitting diode chips 14 are separated into individual die only by a dicing process. Due to the thickness limitation, a relatively simpler breaker machine can not be used.

U.S. Pat. No. 7,732,233 discloses a light emitting diode package structure. The reliability of the light emitting diode is improved by the material characteristic of an Si-substrate and the arrangement of the connectors, the photo-electronic devices, the depressions and the solder bumps. The depressions are firstly formed, and then the light emitting diode chip is formed in the depressions. Next, a planar layer and an encapsulant layer are sequentially formed on the light emitting diode chip. However, the package structure is complex and the fabrication method is tedious.

Therefore, there is a need to develop a light emitting diode package structure with a fabrication method which is simpler than that of prior art, wherein the light emitting diode chip is separated into individual die by a less complex breaker machine.

### BRIEF SUMMARY OF THE INVENTION

The present invention provides a light emitting diode package structure, including: a substrate; a light emitting diode chip formed on a substrate; a first hydrophobic rib layer formed on the substrate and surrounding the light emitting diode; and a first cover layer formed on the substrate and covering the light emitting diode, wherein the first hydrophobic rib layer is used as a border of the first cover layer and an angle between the facet of the first cover layer and the substrate is about 60-90 degrees.

The invention provides a method for fabricating a light emitting diode package structure, including: providing a substrate; forming a first hydrophobic rib layer on the substrate; forming a light emitting diode chip on the substrate, wherein the light emitting diode chip is disposed in a region surrounded by the first hydrophobic rib layer; and forming a first cover layer on the substrate and covering the light emitting diode, wherein the first hydrophobic rib layer is used as a border of the first cover layer and an angle between the facet of the first cover layer and the substrate is about 60-90 degrees.

A detailed description is given in the following embodiments with reference to the accompanying drawings.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a cross-sectional schematic representation of a light emitting diode package structure in prior art;

FIG. 2A shows a cross-sectional schematic representation of a light emitting diode package structure in accordance with an embodiment of the present invention;

FIG. 2B shows a top-view schematic representation of a light emitting diode package structure in accordance with an embodiment of the present invention;

FIGS. 3A-3C show a series of top-view schematic representations of the first hydrophobic rib layer in accordance with various embodiments of the present invention;

FIG. 4 shows a top-view schematic representation of the first cover layer in accordance with an embodiment of the present invention;

FIG. 5 shows a cross-sectional schematic representation of a light emitting diode package structure in accordance with a second embodiment of the present invention;

FIG. 6 shows a cross-sectional schematic representation of a light emitting diode package structure in accordance with a third embodiment of the present invention;

FIG. 7 shows a cross-sectional schematic representation of a light emitting diode package structure in accordance with a fourth embodiment of the present invention; and

FIG. 8 shows a cross-sectional schematic representation of a light emitting diode package structure having a plurality of light emitting diode chips in accordance with an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

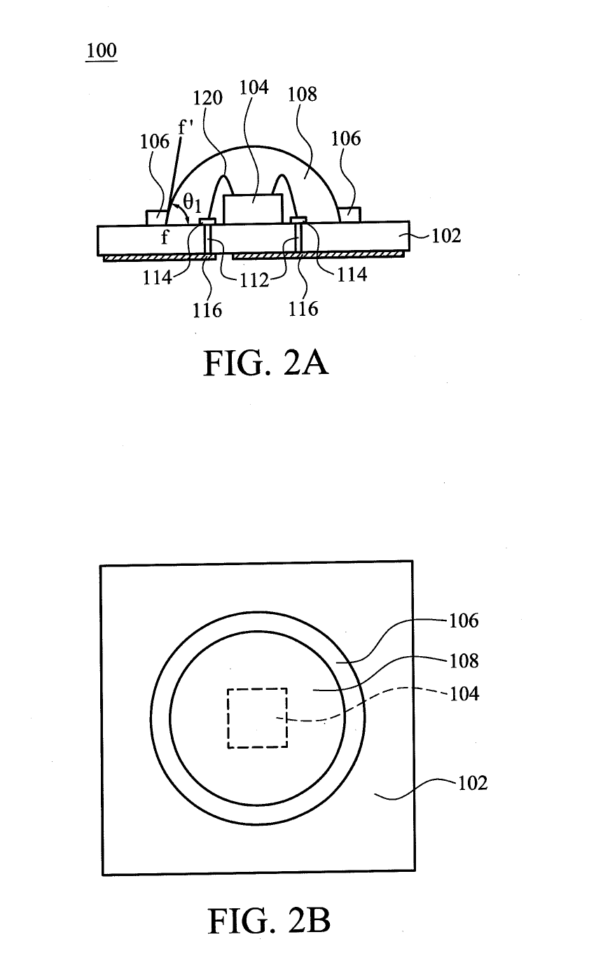

FIG. 2A shows a light emitting diode package structure 100. The light emitting diode package structure 100 includes a substrate 102, a light emitting diode chip 104, a first hydrophobic rib layer 106 and a first cover layer 108. The light emitting diode chip 104 is formed on a substrate; the first hydrophobic rib layer 106 is formed on the substrate 102 and surrounds the light emitting diode 104, and a first cover layer 108 is formed on the substrate 102 and covers the light emitting diode 104.

Additionally, the light emitting diode package structure 100 of the invention further includes a plurality of through holes 112 formed in the substrate, a plurality of first conductive pads 114 formed on the through holes 112, a plurality of second conductive pads 116 formed below the through holes 112, and a plurality of conductive lines 120 formed on the light emitting diode chip 104, wherein the light emitting diode chip 104 is electrically connected to the second conductive pads 116 by the conductive lines 120, the first conductive pads 114 and the through holes 112.

Note that the electrical connection between the first conductive pads 114 and the second conductive pads 116 is shortened by the help of the through holes 112. Thus, the electrically transmission distance is shortened.

The substrate 102 includes Al₂O₃, AlN, silicon, SiC, copper, copper alloy, aluminum, aluminum alloy, metal core printed circuit board (MCPCB), direct bond copper (DBC), FR4 or FR5.

The first hydrophobic rib layer 106 includes fluorine-based materials or silane-based materials, such as Teflon or tetraethoxy-silane nanocrystalline structure. The first hydrophobic rib layer 106 includes transparent materials or non-transparent materials.

The first cover layer 108 includes silicone, epoxy, glass or combinations thereof.

FIG. 2B shows a top-view of FIG. 2A. The pattern of the first hydrophobic rib layer 106 is circular and has a thickness of about 10-500 μm. The light emitting diode chip 104 is surrounded by the first hydrophobic rib layer 106.

Note that the first hydrophobic rib layer 106 is used as a border of the first cover layer 108 to inhibit the overflow problem of the first cover layer 108. Additionally, the first cover layer 108 has a convex structure due to the hydrophobic properties of the surface of the first hydrophobic rib layer 106. The light extraction efficiency of the light emitting diode chip 104 is improved due to the convex structure of the first cover layer 108. An angle θ₁ between the facet ff′ of the first cover layer 108 and the substrate 102 is about 60-90 degrees.

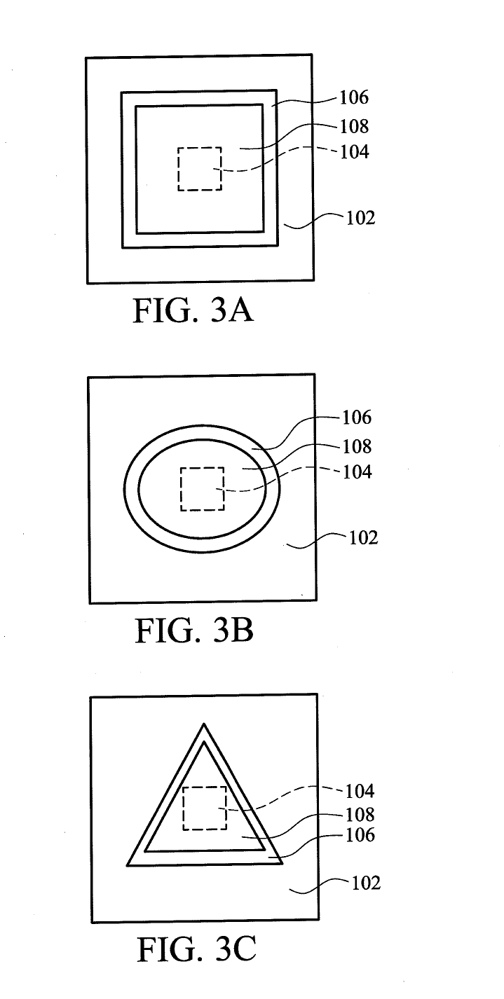

FIGS. 3A-3C show a series of top-views of the first hydrophobic rib layer 106 in various embodiments.

In FIG. 3A, the pattern of the first hydrophobic rib layer 106 is rectangular. In FIG. 3B, the pattern of the first hydrophobic rib layer 106 is elliptic. In FIG. 3C, the pattern of the first hydrophobic rib layer 106 is triangular. Furthermore, other regular or irregular shapes are all included in the scope of the invention, wherein only the light emitting diode chip 104 is surrounded by the first hydrophobic rib layer 106.

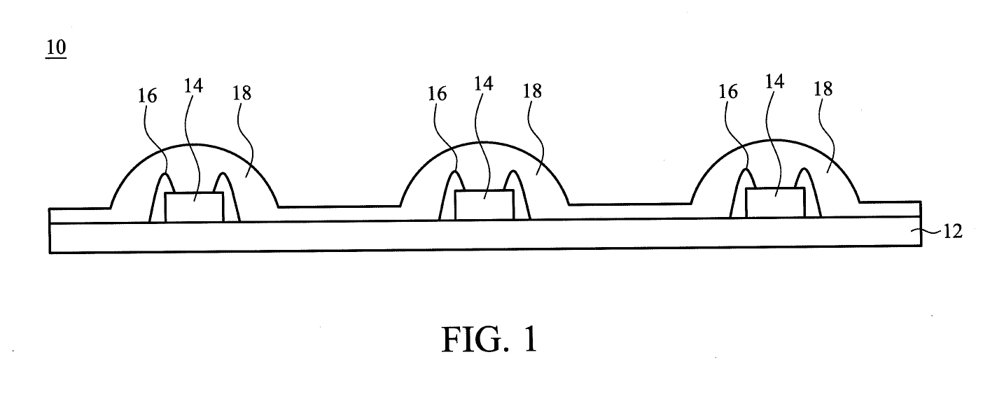

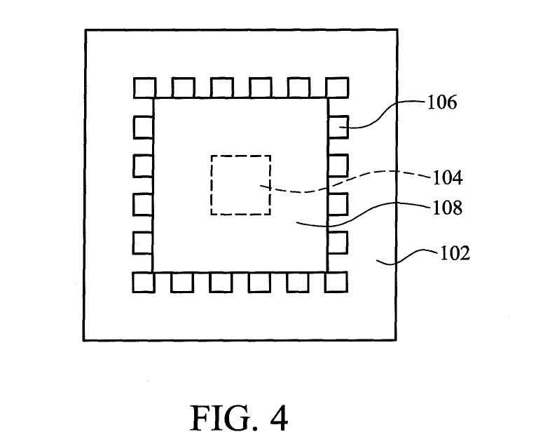

FIG. 4 shows another embodiment of the first hydrophobic rib layer 106. The FIG. 4 is similar to FIG. 1. The difference between FIG. 4 and FIG. 1 is that the first hydrophobic rib layer 106 in FIG. 1 is a continuous block and the first hydrophobic rib layer 106 in FIG. 4 is a non-continuous block.

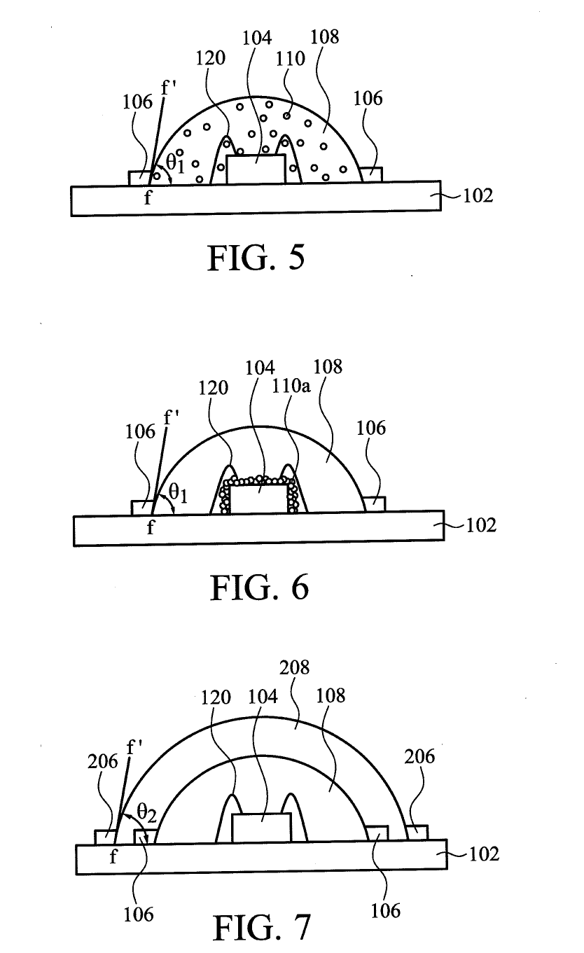

FIG. 5 shows a second embodiment of a light emitting diode package structure, wherein like elements are identified by the same reference numbers as in FIG. 2A, and thus omitted for brevity.

In FIG. 5, the first cover layer 108 further includes a dopant 110. The dopant 110 includes the light diffusion particles or the light wavelength conversion particles. The function of dopant 110 is to improve the uniformity of the spatial light color of the light emitting diode chip 104 and to produce a different light color from that of the light emitting diode chip 104.

The light diffusion particles include SiO₂, Al₂O₃, TiO₂, CaF₂, CaCO₃, BaSO₄ or combinations thereof.

The light wavelength conversion particles include Yttrium aluminum garnet (YAG) phosphor, silicate phosphor, Terbium aluminum garnet (TAG) phosphor, oxide phosphor, nitride phosphor, aluminum oxide phosphor or combinations thereof.

FIG. 6 shows a third embodiment of a light emitting diode package structure. In FIG. 6, a dopant layer 110a is formed on a surface of the light emitting diode chip 104. The dopant layer 110a includes the light diffusion layer or the light wavelength conversion layer. The function of dopant 110a is to improve the uniformity of the spatial light color of the light emitting diode chip 104 and to produce a different light from that of the light emitting diode chip 104.

FIG. 7 shows a fourth embodiment of a light emitting diode package structure, wherein like elements are identified by the same reference numbers as in FIG. 2A, and thus omitted for brevity.

The difference between FIG. 7A and FIG. 2 is that a second hydrophobic rib layer 206 and a second cover layer 208 is added in FIG. 7. The second hydrophobic rib layer 206 is formed on the substrate 102 and surrounds the first hydrophobic rib layer 106, and the second cover layer 208 is formed on the substrate 102 and the first cover layer 108, wherein the second hydrophobic rib layer 206 is used as a border of the second cover layer 208 and an angle θ₂ between the facet ff′ of the second cover layer 208 and the substrate 102 is about 60-90 degrees.

Additionally, in other embodiments, the second cover layer 208 further includes a dopant (not shown in FIG. 7). The dopant includes the light diffusion particles or the light wavelength conversion particles. The function of dopant is to improve the uniformity of the spatial light color of the light emitting diode chip 104 and to produce a different light from that of the light emitting diode chip 104.

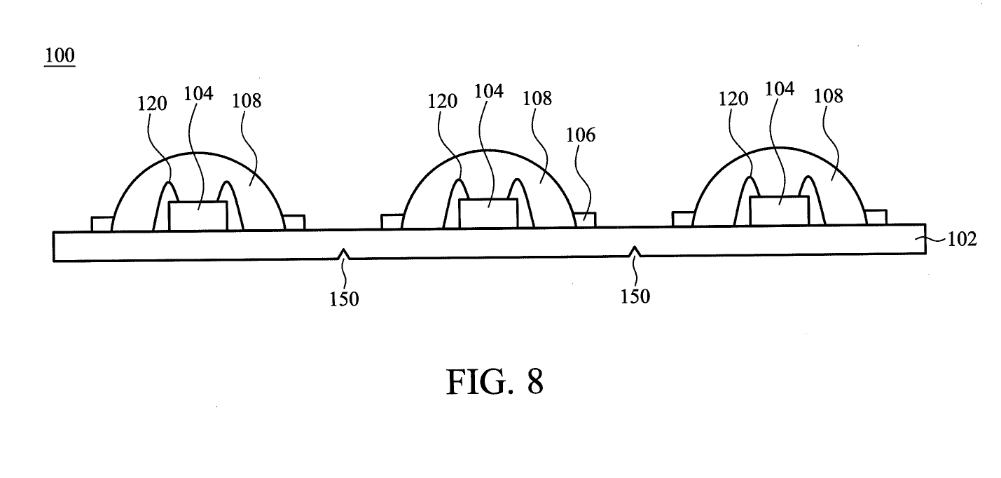

FIG. 8 shows a light emitting diode package structure of the invention having a plurality of light emitting diode chips. There are three light emitting diode chips in FIG. 8. The number of the light emitting diode chips is merely exemplary and not meant to limit the invention. The number of light emitting diode chips may be adjusted according to actual applications.

Note that the first hydrophobic rib layer 106 is used as a border of the first cover layer 108, and thus the overflow problem of the first cover layer 108 between the adjacent light emitting diode chips is inhibited.

In prior art, referring to FIG. 1, the light emitting diode chips are separated into individual die only by a dicing process. By the design of the first hydrophobic rib layer 106, the light emitting diode chips 104 of the invention are separated into individual die by a laser cutting process, a blade cutting process or a breaker machine (along a cutting line 150, referring to FIG. 8).

Additionally, referring to FIG. 2A, the invention provides a method for fabricating a light emitting diode package structure, including the following steps. A substrate 102 is firstly provided. Then, a first hydrophobic rib layer 106 is formed on the substrate 102. The first hydrophobic rib layer 106 is formed by a dispensing process, screening process, laminate adhesive process, lithography process, printing process or deposition process.

Next, a light emitting diode chip 104 is formed on the substrate, wherein the light emitting diode chip 104 is disposed in a region surrounded by the first hydrophobic rib layer 106.

Then, a first cover layer 108 is formed on the substrate and covers the light emitting diode 104, wherein the first hydrophobic rib layer 106 is used as a border of the first cover layer 108 and an angle between the facet ff′ of the first cover layer 108 and the substrate 102 is about 60-90 degrees. The first cover layer 108 is formed by a dispensing process, screening process, molding process or laminate adhesive process.

Note that in prior art, a convex structure of the encapsulant is formed by a molding process with a mold. The convex structure of the first cover layer 108 of the invention is easily formed by using a less complex dispensing process for the first hydrophobic rib layer 106.

Besides the above-mentioned steps, a dopant 110 is further formed in the first cover layer 108 to form the package structure of FIG. 5, wherein the dopant 110 includes the light diffusion particles or the light wavelength conversion particles.

Besides the above-mentioned steps, before forming the first cover layer 108, a dopant layer 110a is further formed on a surface of the light emitting diode chip 104 to form the package structure of FIG. 6. The dopant layer 110a includes the light diffusion layer or the light wavelength conversion layer.

The package structure of FIG. 7 is formed by the following steps. A second hydrophobic rib layer 206 is formed on the substrate 102 and surrounds the first hydrophobic rib layer 106. A second cover layer 208 is formed on the substrate 102 and the first cover layer 108, wherein the second hydrophobic rib layer 206 is used as a border of the second cover layer 208 and an angle θ₂ between the facet f₁f₁′ of the second cover layer 208 and the substrate 102 is about 60-90 degrees.

From the above descriptions, the light emitting diode package structure and method for fabricating the same has the following advantages:

(1) The first hydrophobic rib layer 106 is used as a border of the first cover layer 108 to inhibit the overflow problem of the first cover layer 108.

(2) The first cover layer 108 has a convex structure due to the hydrophobic properties of the surface of the first hydrophobic rib layer 106. The light extraction efficiency of the light emitting diode chip 104 is improved due to the convex structure of the first cover layer 108.

(3) By the design of the first hydrophobic rib layer 106, the light emitting diode chips 104 of the invention are separated into individual die by a laser cutting process, a blade cutting process or a breaker machine (along a cutting line 150, referring to FIG. 8).

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting diode package structure, comprising:
a substrate;
a light emitting diode chip formed on a substrate;
a first hydrophobic rib layer formed on the substrate and surrounding the light emitting diode; and
a first cover layer formed on the substrate and covering the light emitting diode, wherein the first hydrophobic rib layer is used as a border of the first cover layer and an angle between the facet of the first cover layer and the substrate is about 60-90 degrees.

2. The light emitting diode package structure as claimed in claim 1, wherein the substrate comprises Al₂O₃, AlN, silicon, SiC, copper, copper alloy, aluminum, aluminum alloy, metal core printed circuit board (MCPCB), direct bond copper (DBC), FR4 or FR5.

3. The light emitting diode package structure as claimed in claim 1, wherein the first hydrophobic rib layer comprises fluorine-based materials or silane-based materials.

4. The light emitting diode package structure as claimed in claim 1, wherein the first hydrophobic rib layer comprises transparent materials or non-transparent materials.

5. The light emitting diode package structure as claimed in claim 1, wherein the pattern of first hydrophobic rib layer comprises circle, rectangular, elliptic, rhombus, triangular or irregular shapes.

6. The light emitting diode package structure as claimed in claim 1, wherein the first hydrophobic rib layer has a thickness of about 10-500 μm.

7. The light emitting diode package structure as claimed in claim 1, wherein the first cover layer comprises silicone, epoxy, glass or combinations thereof.

8. The light emitting diode package structure as claimed in claim 1, wherein the first cover layer comprises a continuous block or non-continuous block.

9. The light emitting diode package structure as claimed in claim 5, wherein the first cover layer further comprises the light diffusion particles or the light wavelength conversion particles.

10. The light emitting diode package structure as claimed in claim 9, wherein the light diffusion particles comprise SiO₂, Al₂O₃, TiO₂, CaF₂, CaCO₃, BaSO₄ or combinations thereof.

11. The light emitting diode package structure as claimed in claim 9, wherein the light wavelength conversion particles comprise Yttrium aluminum garnet (YAG) phosphor, silicate phosphor, Terbium aluminum garnet (TAG) phosphor, oxide phosphor, nitride phosphor, aluminum oxide phosphor or combinations thereof.

12. The light emitting diode package structure as claimed in claim 1, further comprising a light diffusion layer or a light wavelength conversion layer formed on a surface of the light emitting diode chip.

13. The light emitting diode package structure as claimed in claim 1, further comprising:
a second hydrophobic rib layer formed on the substrate and surrounding the first hydrophobic rib layer; and
a second cover layer formed on the substrate and the first cover layer, wherein the second hydrophobic rib layer is used as a border of the second cover layer and an angle between the facet of the second cover layer and the substrate is about 60-90 degrees.

14. The light emitting diode package structure as claimed in claim 1, further comprising:
a plurality of through holes formed in the substrate;
a plurality of first conductive pads formed on the through holes, and a plurality of second conductive pads formed below the through holes;
a plurality of conductive lines formed on the light emitting diode chip, wherein the light emitting diode chip is electrically connected to the second conductive pads by the conductive lines, the first conductive pads and the through holes.

15. A method for fabricating a light emitting diode package structure, comprising steps of:
providing a substrate;
forming a first hydrophobic rib layer on the substrate;
forming a light emitting diode chip on the substrate, wherein the light emitting diode chip is disposed in a region surrounded by the first hydrophobic rib layer; and
forming a first cover layer on the substrate and covering the light emitting diode, wherein the first hydrophobic rib layer is used as a border of the first cover layer and an angle between the facet of the first cover layer and the substrate is about 60-90 degrees.

16. The method for fabricating the light emitting diode package structure as claimed in claim 15, wherein the first hydrophobic rib layer is formed by a dispensing process, screening process, laminate adhesive process, lithography process, printing process or deposition process.

17. The method for fabricating the light emitting diode package structure as claimed in claim 15, wherein the first cover layer is formed by a dispensing process, screening process, molding process or laminate adhesive process.

18. The method for fabricating the light emitting diode package structure as claimed in claim 15, further comprising:
forming the light diffusion particles or the light wavelength conversion particles in the first cover layer.

19. The method for fabricating the light emitting diode package structure as claimed in claim 15, before forming the first cover layer, further comprising:
forming a light diffusion layer or a light wavelength conversion layer on a surface of the light emitting diode chip.

20. The method for fabricating the light emitting diode package structure as claimed in claim 15, further comprising:
forming a second hydrophobic rib layer on the substrate and surrounding the first hydrophobic rib layer; and
forming a second cover layer on the substrate and the first cover layer, wherein the second hydrophobic rib layer is used as a border of the second cover layer and an angle between the facet of the second cover layer and the substrate is about 60-90 degrees.
